(19) United States
(12) Patent Application Publication
(10) Pub. No.: US 2025/0226328 A1
(43) Pub. Date: Jul. 10, 2025

(54) MULTILAYER CORELESS SUBSTRATE FORMED FROM STACKED EMBEDDED TRACE SUBSTRATES

(71) Applicant: QUALCOMM Incorporated, San Diego, CA (US)

(72) Inventors: Kyudong KANG, Seoul (KR); Heun Gun SHIN, San Diego, CA (US); Myungryul CHOI, Paju (KR)

(21) Appl. No.: 18/407,933

(22) Filed: Jan. 9, 2024

(51) Int. Cl. H01L 23/538; H01L 21/48; H01L 23/00; H01L 23/498

(52) U.S. Cl. CPC H01L 23/5386; H01L 21/4857; H01L 23/49816; H01L 23/5383; H01L 24/16; H01L 2224/16227

(57) ABSTRACT

An electronic device including a substrate is disclosed. In an aspect, the substrate includes at least two stacked embedded trace substrates (ETS); a first dielectric layer disposed between an internally facing surface of a first ETS of the at least two stacked ETS with an internally facing surface of a second ETS of the at least two stacked ETS; and a first set of one or more metal connectors that extends through the first dielectric layer and couples a first set of one or more metal structures at the internally facing surface of the first ETS with a second set of one or more metal structures at the internally facing surface of the second ETS.

### FIELD OF DISCLOSURE

The present disclosure generally relates to electronic packaging, and more particularly, to multilayer coreless substrates formed from stacked embedded trace substrates.

### BACKGROUND

Integrated circuit (IC) technology has achieved great strides in advancing computing power through miniaturization of electrical components. An IC may be implemented as an IC chip with a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system-on-a-chip (SOC) devices, which may include multiple function blocks, with each function block designed to perform a specific function, such as, for example, a microprocessor function, a graphics processing unit (GPU) function, a communications function (e.g., WiFi, Bluetooth, and other communications), and the like.

Printed Circuit Boards (PCBs) are integral components in contemporary electronic packaging, serving as the platform for mounting and interconnecting various electronic components. The evolution of PCB technology has been driven by the requirements of advanced electronics, leading to the development of structures that support increased circuit density and reduced form factors. With the trend toward device miniaturization come stricter requirements for PCBs including higher interconnect densities and precise metallization routing and placement.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an electronic device comprises: a substrate, the substrate comprising: at least two stacked embedded trace substrates (ETS); a first dielectric layer disposed between an internally facing surface of a first ETS of the at least two stacked ETS with an internally facing surface of a second ETS of the at least two stacked ETS; and a first set of one or more metal connectors that extends through the first dielectric layer and couples a first set of one or more metal structures at the internally facing surface of the first ETS with a second set of one or more metal structures at the internally facing surface of the second ETS.

In an aspect, a substrate comprising: at least two stacked embedded trace substrates (ETS) overlying one another; a first dielectric layer joining an internally facing surface of a first ETS of the at least two stacked ETS with an internally facing surface of a second ETS of the at least two stacked ETS; and a first set of one or more metal structures extending through the first dielectric layer and connecting a first set of one or more metal structures at the internally facing surface of the first ETS with a second set of one or more metal structures at the internally facing surface of the second ETS.

In an aspect, a method of fabricating a substrate includes aligning at least two stacked embedded trace substrates (ETS) to overlie one another, wherein the at least two stacked ETS include a first ETS having an internally facing surface having a first set of one or more metal connectors, and a second ETS having an internally facing surface having a first set of one or more metal structures; aligning a first dielectric layer between the internally facing surface of the first ETS and the internally facing surface of the second ETS; and joining the internally facing surface of the first ETS and the internally facing surface of the second ETS with the first dielectric layer, wherein the joining connects at least one metal structure of the first set of one or more metal connectors at the internally facing surface of the first ETS with at least one metal structure of the first set of one or more metal structures at the internally facing surface of the second ETS.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 shows an example multilayer coreless substrate, according to aspects of the disclosure.

FIG. 2 is a top-plan view of the example multilayer coreless substrate, according to aspects of the disclosure.

FIG. 3 is an exploded cross-sectional view of the structures of a multilayer coreless substrate, according to aspects of the disclosure.

FIG. 4 is a cross-sectional view of an example multilayer coreless substrate, according to aspects of the disclosure.

FIG. 5 is a partial top plan view of the example multilayer coreless substrate, according to aspects of the disclosure.

FIG. 6 illustrates an example electronic package that includes a multilayer coreless substrate, according to aspects of the disclosure.

FIG. 7A through FIG. 7F show example operations that may be used to fabricate embedded trace substrates (ETS), according to aspects of the disclosure.

FIG. 8A through FIG. 8D show exemplary operations that may be used to form a multilayer coreless substrate using stacked ETS, according to aspects of the disclosure.

FIG. 9 shows example operations of a method of fabricating a substrate, according to aspects of the disclosure.

FIG. 10 illustrates a profile view of a package that includes a multilayer coreless substrate, an integrated device, and an integrated passive device, according to aspects of the disclosure.

FIG. 11 illustrates an example method for providing or fabricating a package that includes an integrated device comprising an electronic component, according to aspects of the disclosure.

FIG. 12 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC).

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

Coreless substrate PCBs have emerged as an alternative to traditional PCBs. By design, coreless substrate PCBs do not incorporate a central core material. Instead, they are constructed using layers of thin insulating materials. The absence of a core contributes to a reduction in the PCB's overall thickness, which is advantageous for applications requiring compact electronic assemblies. The use of a coreless structure in PCBs facilitates several functional improvements, including the potential for shorter electrical pathways and more direct routing configurations. These attributes can contribute to efficient signal transmission and are advantageous in the context of high-density interconnect (HDI) applications. Additionally, the structure allows for closer stacking of layers, which can be beneficial in creating a higher number of interconnections within a confined space.

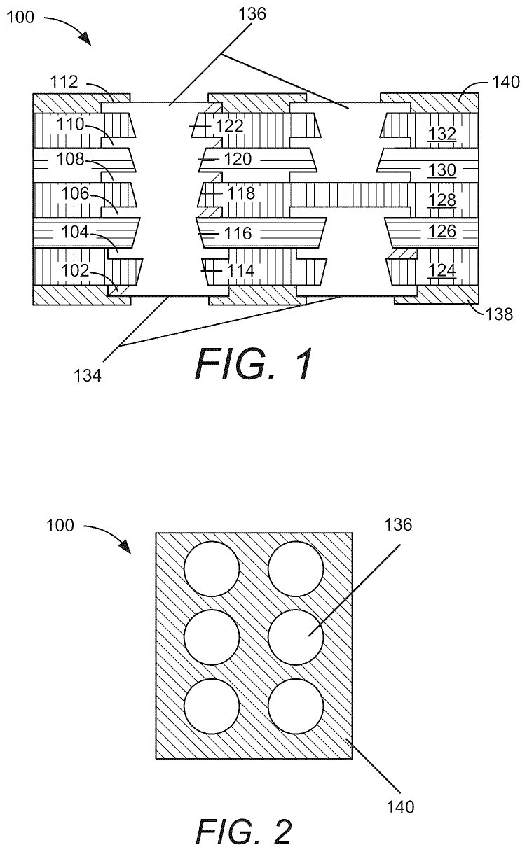

FIG. 1 shows an example multilayer coreless substrate 100, according to aspects of the disclosure. In this example, the multilayer coreless substrate 100 is a six-layer substrate having six patterned metallization layers 102, 104, 106, 108, 110, and 112 formed over respective dielectric layers 124, 126, 128, 130, and 132. Metallized vias 114, 116, 118, 120, and 122 extend through the dielectric layers 124, 126, 128, 130, and 132 to selectively interconnect the patterned metallization layers 102, 104, 106, 108, 110, and 112. The patterned metallization layer 102 includes the pads 134 that extend beyond the surface of the dielectric layer 124. Similarly, the patterned metallization layer 112 includes pads 136 that extend beyond the surface of the dielectric layer 132. In an aspect, the pads 136 may be used as connection points to which components (e.g., integrated circuit dies, passive components, etc.) disposed at the upper surface of the multilayer coreless substrate 100 are soldered. Similarly, the pads 134 may be used as connection points for soldering the multilayer coreless substrate 100 to a printed circuit board or connection points to which components disposed that the lower surface of the coreless substrate are soldered. Since the pads 134 extend beyond the surface of dielectric layer 124, a patterned solder mask layer 138 is formed over the outer surface of the dielectric layer 124 and over portions of the pads 134 that are to be protected from solder material. Likewise, since the pads 136 extend beyond the surface of dielectric layer 132, a patterned solder mask layer 140 is formed over the outer surface of the dielectric layer 132 and over portions of the pads 136 that are to be protected from any soldering material. In an aspect, the solder mask layers 138 and 140 may have a thickness between 12-15 micrometers on each side and can be costly to process. In accordance with certain aspects of the disclosure, a multilayer coreless substrate may be formed that does not need solder mask layers thereby reducing manufacturing costs associated with the solder mask processes. Additionally, in accordance with certain aspects of the disclosure, the thickness of the substrate may be reduced with the omission of such solder mask layers.

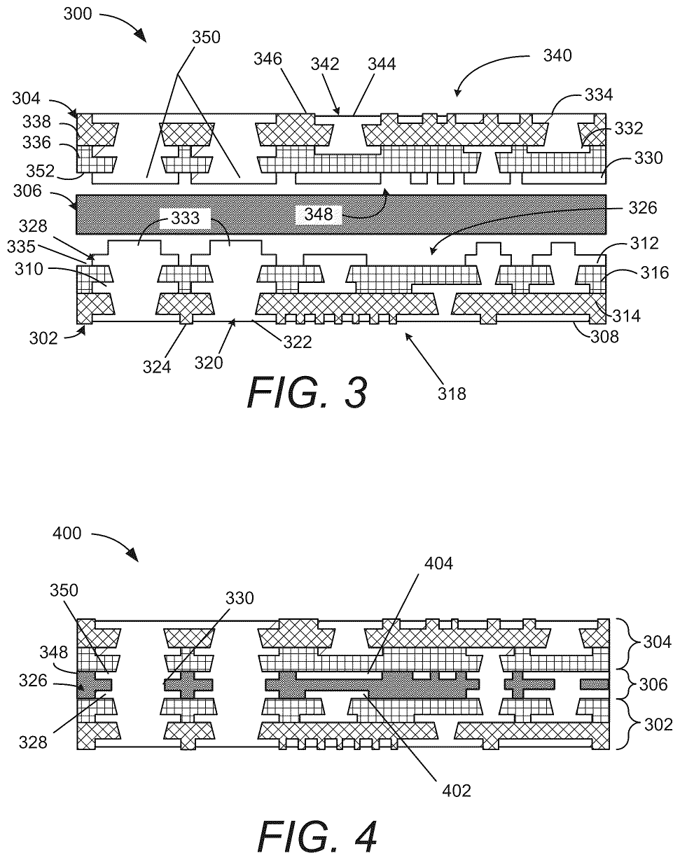

FIG. 2 is a top plan view of the example multilayer coreless substrate 100, according to aspects of the disclosure. In this example, the upper surface of the multilayer coreless substrate 100 is covered with the patterned solder mask layer 140, leaving only portions of the pads 136 exposed during subsequent soldering of components to the multilayer coreless substrate 100. The lower surface of the multilayer coreless substrate 100 is similarly formed with the patterned solder mask layer 138, leaving only a portion of the pads 134 exposed during subsequent soldering of components to the multilayer coreless substrate 100.

The conventional processes used to fabricate a multilayer coreless substrate (e.g., multilayer coreless substrate 100) can be expensive to implement and difficult to execute, particularly as the number of required layers increases. Typically, a complex sequence of dry film resist (DFR) lamination/delamination, laser drilling, seed layer deposition/etching, and electroplating/etching operations are needed. In scenarios mandating precise alignment and placement of fine metallization lines, obtaining the necessary control over the dimensions and spacings of the metallized lines may be difficult to achieve using the conventional coreless substrate fabrication processes.

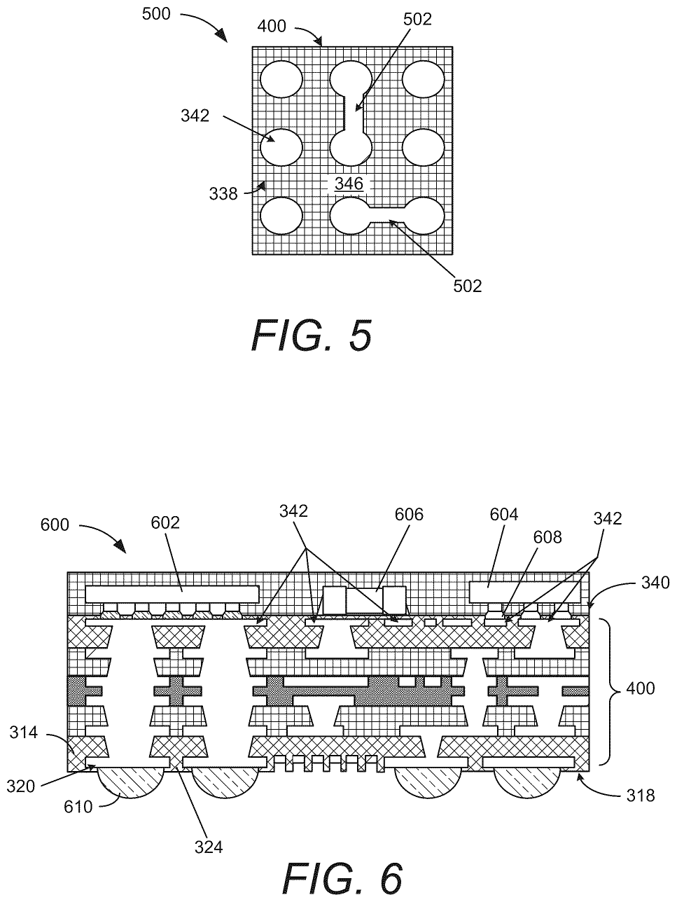

FIG. 3 is an exploded cross-sectional view of the structures 300 of a multilayer coreless substrate, according to aspects of the disclosure. In this example, the structures 300 include at least two embedded trace substrates (ETS) 302 and 304 and a dielectric layer 306. The ETS 302 is a three-layer ETS structure having three metallization layers 308, 310, and 312 formed on two dielectric layers 314 and 316. The outer surface 318 of the ETS 302 includes a plurality of pads 320 formed by metallization layer 308 that are embedded in the dielectric layer 314 where the outer surfaces 322 of the pads 320 are recessed from the outer surface 324 of the dielectric layer 314. Given this relationship between the outer surfaces 322 of the pads 320 with respect to the outer surface 324 of the dielectric layer 314, the pads 320 may be referenced as “recessed pads.”

The internally facing surface 326 of the ETS 302 includes a plurality of pads 328 formed by metallization layer 312 that extend above the interior surface 335 of the dielectric layer 316. In an aspect, an “internal surface” and/or an “internally facing surface” refers to a surface that will ultimately be disposed at the inside of the multilayer coreless substrate structure. Given this relationship between the pads 328 with respect to the interior surface 335 of the dielectric layer 316, the pads 328 may be referenced as “raised pads.” Some of the raised pads 328 include metallization bumps 333 formed over the upper surfaces of the raised pads 328 that effectively extend the height of certain raised pads 328.

The ETS 304 is also a three-layer ETS structure having three metallization layers 330, 332, and 334 formed on two dielectric layers 336 and 338. The outer surface 340 of the ETS 304 includes a plurality of recessed pads 342 formed by metallization layer 334 that are embedded in the dielectric layer 338 where the outer surfaces 344 of the pads 342 are recessed from the outer surface 346 of the dielectric layer 338. The internally facing surface 348 of the ETS 304 includes a plurality of raised pads 350 formed by metallization layer 330 that extend above the interior surface 352 of the dielectric layer 336.

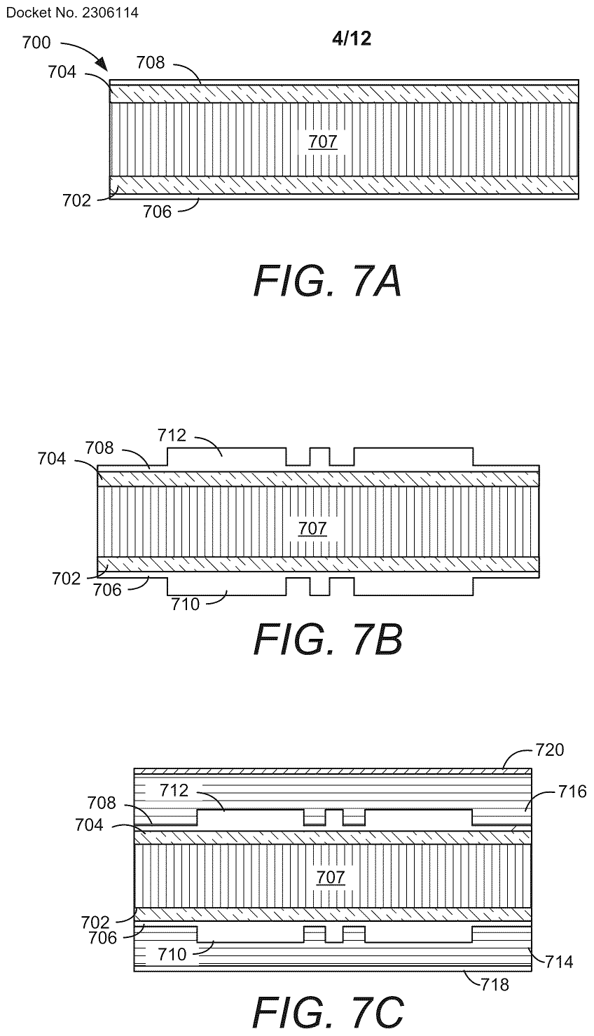

FIG. 4 is a cross-sectional view of an example multilayer coreless substrate 400, according to aspects of the disclosure. In this example, the internally facing surfaces 326 and 348 of the ETS 302 and 304 are joined with the dielectric layer 306. A set of metallization structures (e.g., metallized bumps 333) extend through the dielectric layer 306 and connect a set of metallization structures (e.g., raised pads 328) at the internally facing surface 326 of the ETS 302 with a set of metallization structures (e.g., raised pads 350) at the internally facing surface 348 of the ETS 304. Certain raised pads (e.g., raised pads 402 and 404) are not associated with a corresponding metallized bump and, therefore, are electrically isolated from one another by the dielectric material of the dielectric layer 306. It will be recognized, based on the teachings of the present disclosure, that the metallized bumps 333 may be formed on the raised pads 328, raised pads 350, or both raised pads 328 and 350 provided that the metallized bumps 333 have a height that is sufficient to connect the raised pads 328 and 350 through the dielectric layer 306.

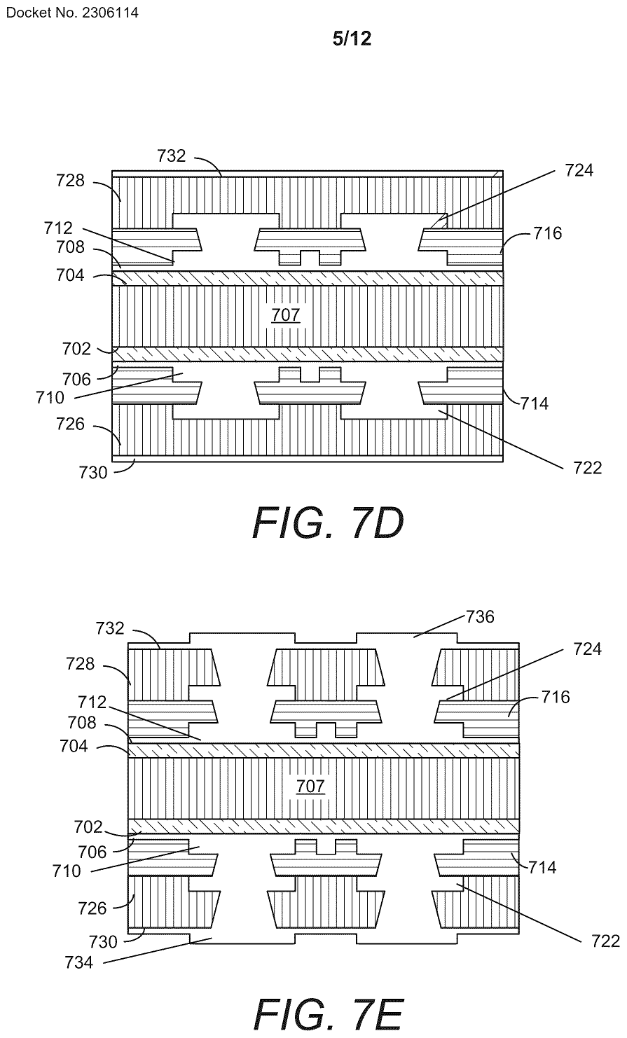

FIG. 5 is a partial top plan view 500 of the example multilayer coreless substrate 400, according to aspects of the disclosure. Unlike the multilayer coreless substrate 100 (see FIG. 1 and FIG. 2), the outer surface 346 of the dielectric layer 338 need not be covered with a solder mask layer since the recessed pads 342 are recessed from the surface 346 and are less likely to be subject to shorts when solder is applied to connect the recessed pads 342 with electronic components mounted to the multilayer coreless substrate 400. In accordance with certain aspects of the disclosure, the metallization lines 502 (e.g., traces) interconnecting the recessed pads 342 may also be recessed from the surface 346 and exposed without the need for an overlying solder mask. Without solder mask layers, the overall thickness of the total substrate may be reduced compared to substrates having solder mask layers. In an aspect, both sides of the substrate may be made available for making small pitch flip chip pads and solder ball pads since there is no need to consider solder mask registration when making such structures. In an aspect, the fabrication costs may be reduced, and shorter manufacturing lead times may be achieved.

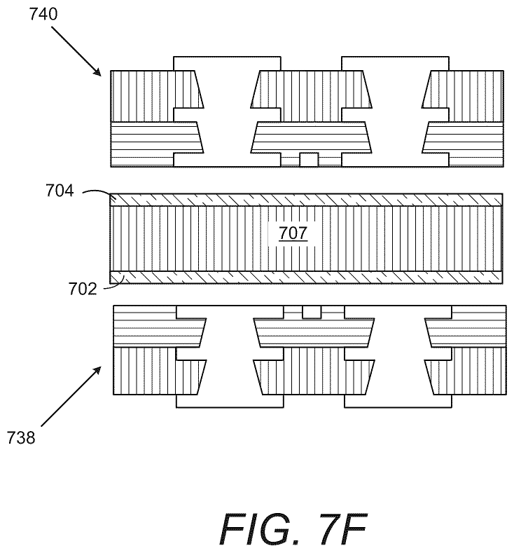

FIG. 6 illustrates an example electronic package 600 that includes a multilayer coreless substrate 400, according to aspects of the disclosure. In this example, various electronic components are attached to the outer surface 340 the multilayer coreless substrate 400. In an aspect, the electronic components may include surface-mounted ICs 602 and 604 and one or more passive components 606, such as resistors and/or capacitors. In an aspect, the terminals of the electronic components may be connected to the recessed pads 342 through solder joints 608. Since the recessed pads 342 are recessed from the outer surface 324 of the dielectric layer 314, a solder mask need not be applied to the outer surface 318.

According to aspects of the disclosure, the outer surface 318 of the multilayer coreless substrate 400 includes solder interconnects 610 that attach to recessed pads 320. In an aspect, the solder interconnects 610 may be used to electrically connect the electronic package 600 to corresponding metal structures of a package substrate (not shown in FIG. 6). Since the recessed pads 320 are recessed from the outer surface 346 of the dielectric layer 338, a solder mask need not be applied to the outer surface 340.

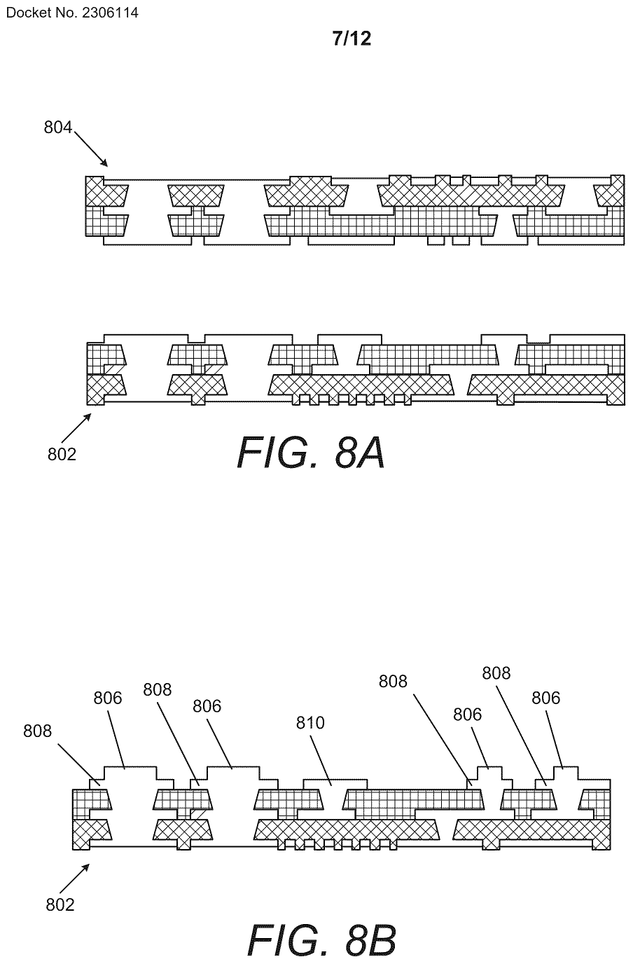

FIG. 7A through FIG. 7F show example operations that may be used to fabricate embedded trace substrates (ETS), according to aspects of the disclosure. FIG. 7A shows a structure 700 on which two ETS structures may be formed. As will be apparent from the following operations, a single multilayer ETS structure is formed on each side of the structure 700. Here, the structure 700 includes a dummy copper clad laminate (CCL) having layers of copper carrier layers 702 and 704 disposed and opposed surfaces of a dielectric core 707. The structure 700 also includes seed layers 706 and 708 (e.g., copper seed layers formed over the copper carrier layers 702 and 704).

FIG. 7B shows the formation of the first level of patterned metallization layers 710 and 712 (e.g., copper metallization layers) over the seed layers 706 and 708. The patterned metallization layers 710 and 712 may be formed using standard processes in which the metallization layers 710 and 712 are electroplated over the seed layers 706 and 708 (e.g., DFR masking, ultraviolet light exposure, development, electroplating, and stripping operations).

In FIG. 7C, dielectric layers 714 and 716 are formed over the seed layers 706 and 708 and the patterned metallization layers 710 and 712. Additionally, seed layers 718 and 720 are formed over the outer surfaces of the dielectric layers 714 and 716 pursuant to forming the next level of patterned metallization layers.

In FIG. 7D, a second level of patterned metallization layers 722 and 724 have been formed using standard processes in which the metallization layers 722 and 724 are electroplated. Once the second level of patterned metallization layers 722 and 724 have been formed, dielectric layers 726 and 728 are formed over the second level of patterned metallization layers 722 and 724. Additionally, seed layers 730 and 732 are formed over the outer surfaces of the dielectric layers 726 and 728 pursuant to forming the next level of patterned metallization layers.

In FIG. 7E, a third level of patterned metallization layers 734 and 736 have been formed using standard processes in which the metallization layers 734 and 736 are electroplated.

In FIG. 7F, two ETS 738 and 740 are formed by detaching the ETS 738 and 740 from the copper carrier layers 702 and 704 of the dummy copper-clad laminate. Pursuant to the detachment process, seed layers 706 and 708 have been removed. Additionally, seed layers 730 and 732 are removed during the detachment process.

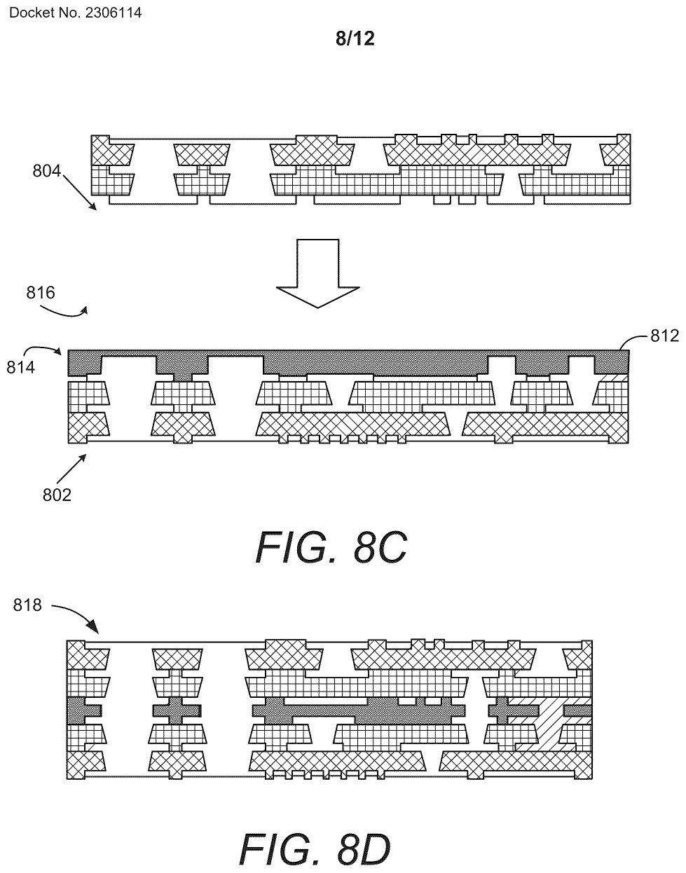

FIG. 8A through FIG. 8D show exemplary operations that may be used to form a multilayer coreless substrate using stacked ETS, according to aspects of the disclosure.

FIG. 8A shows the ETS 802 and 804 that will be joined to form the multilayer coreless substrate.

In FIG. 8B, metallized bumps 806 have been selectively formed over certain raised pads 808 of the ETS 802. In this example, raised pad 810 does not include a metallized bump since the raised pad 810 will not be connected to any metal structures of the ETS 804. In an aspect, the metallized bumps 806 may be formed using a lithography and metal plating (e.g., copper plating) fabrication process. In an aspect, the metallized bumps may be formed using Dry Film Resistor (DFR) lithography and copper (Cu) plating. In an aspect, the process flow may include the following operations: 1) DFR lamination on the seed layer; 2) DFR exposure; 3) DFR development; 4) electrolytic Cu plating; 5) DFR stripping; and 6) seed layer etching.

In FIG. 8C, a dielectric layer 812 is aligned between the interior facing surfaces 814 and 816 of the ETS 802 and 804, and the structures are subject to a hot press operation to form the completed multilayer coreless substrate 818 shown in FIG. 8D. In this example, the structure of the multilayer coreless substrate 818 may have the same structural features as the multilayer coreless substrate 400 shown in described in connection with FIG. 4.

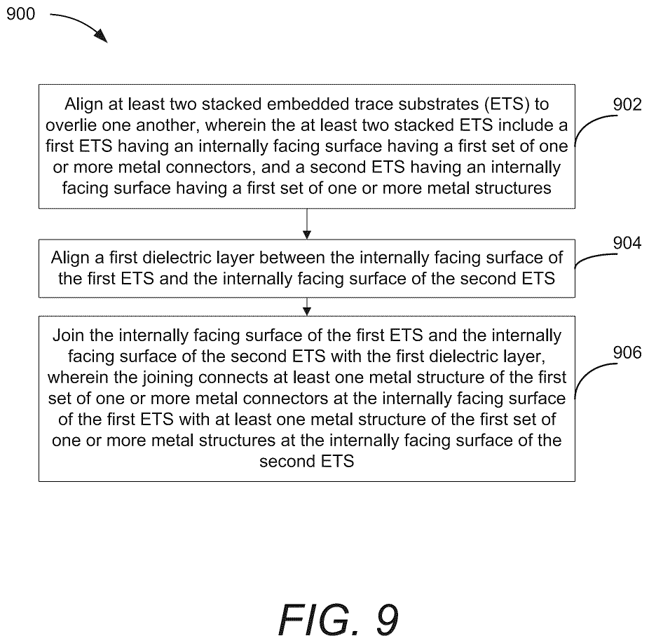

FIG. 9 shows example operations of a method 900 of fabricating a substrate, according to aspects of the disclosure. At operation 902, at least two stacked embedded trace substrates (ETS) are aligned to overlie one another, wherein the at least two stacked ETS include a first ETS having an internally facing surface having a first set of one or more metal connectors, and a second ETS having an internally facing surface having a first set of one or more metal structures At operation 904, a first dielectric layer is aligned between the internally facing surface of the first ETS and the internally facing surface of the second ETS. At operation 906, the internally facing surface of the first ETS and the internally facing surface of the second ETS are joined with the first dielectric layer, wherein the joining connects at least one metal structure of the first set of one or more metal connectors at the internally facing surface of the first ETS with at least one metal structure of the first set of one or more metal structures at the internally facing surface of the second ETS.

A technical advantage of the method 900 is that a multilayer coreless substrate is formed using stacked ETS in a cost-effective manner. In an aspect, the method enables the fabrication of substrates having high-density distribution patterns and multiple layers. The ETS and, as such, the coreless substrate formed using both side of ETS, may be fabricated to have the fine line dimensions and the high precision line placement demanded by the increasing need for package miniaturization and may be used to make thinner packages through the omission of the solder mask layers that are typical required.

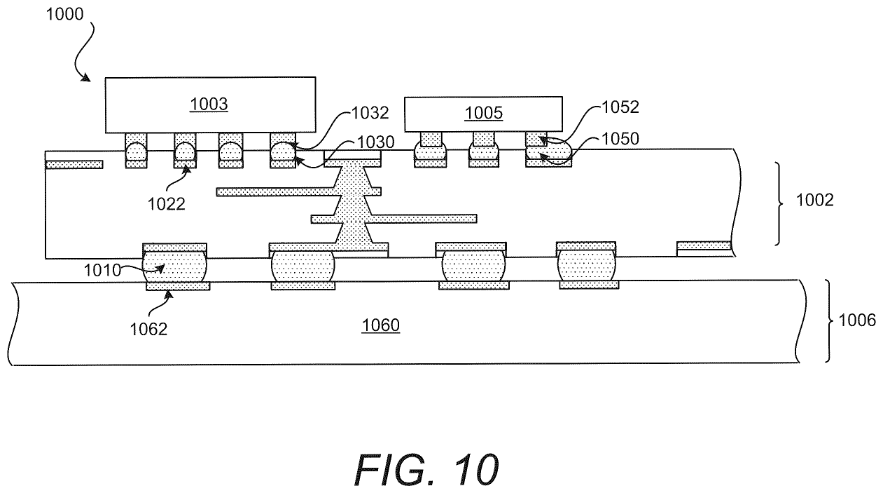

FIG. 10 illustrates a profile view of a package 1000 that includes a multilayer coreless substrate 1002, an integrated device 1003, and an integrated passive device 1005, according to aspects of the disclosure. The package 1000 may be coupled to a printed circuit board (PCB) 1006 through a plurality of solder interconnects 1010. The PCB 1006 may include at least one board dielectric layer 1060 and a plurality of board interconnects 1062.

The multilayer coreless substrate 1002 is formed from multiple stacked ETS, according to aspects of the disclosure. The integrated device 1003 may be coupled to the multilayer coreless substrate 1002 through a plurality of solder interconnects 1030. The integrated device 1003 may be coupled to the multilayer coreless substrate 1002 through a plurality of pillar interconnects 1032 and the plurality of solder interconnects 1030. The integrated passive device 1005 may be coupled to the multilayer coreless substrate 1002 through a plurality of solder interconnects 1050. The integrated passive device 1005 may be coupled to the multilayer coreless substrate 1002 through a plurality of pillar interconnects 1052 and the plurality of solder interconnects 1050.

The package (e.g., 1000) may be implemented in a radio frequency (RF) package. The RF package may be a radio frequency front end (RFFE) package. A package (e.g., 1000) may be configured to provide Wireless Fidelity (WiFi) communication and/or cellular communication (e.g., 2G, 3G, 4G, 5G). The package (e.g., 1000) may be configured to support Global System for Mobile (GSM) Communications, Universal Mobile Telecommunications System (UMTS), and/or Long-Term Evolution (LTE). The package (e.g., 1000) may be configured to transmit and receive signals having different frequencies and/or communication protocols.

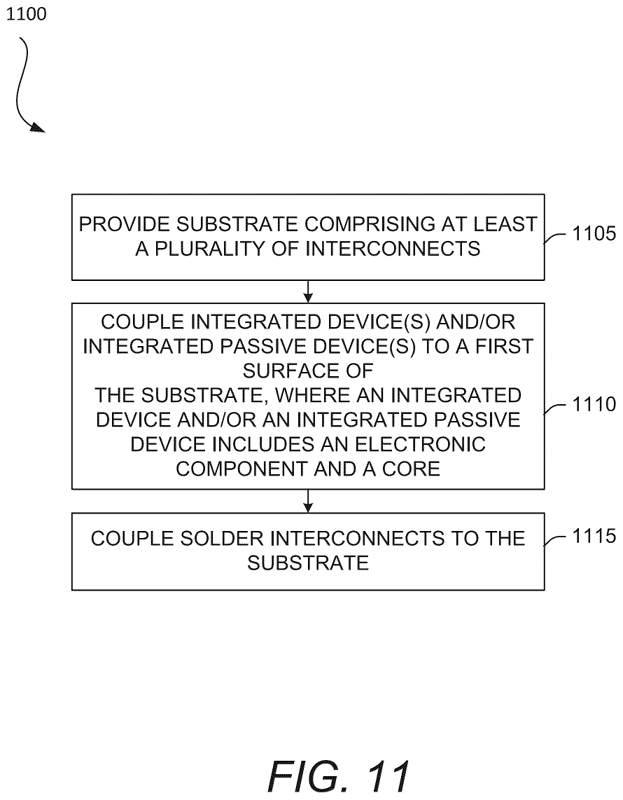

FIG. 11 illustrates an example method 1100 for providing or fabricating a package that includes an integrated device comprising an electronic component, according to aspects of the disclosure. In some implementations, the method 1100 of FIG. 11 may be used to provide or fabricate the package 1000 of FIG. 10 described in the disclosure. However, the method 1100 may be used to provide or fabricate any of the packages described in the disclosure.

It should be noted that the method of FIG. 11 may combine one or more processes in order to simplify and/or clarify the method for providing or fabricating a package that includes an integrated device comprising an electronic component mounted in a core, according to aspects of the disclosure. In some implementations, the order of the processes may be changed or modified.

The method provides (at 1105) a substrate (e.g., 1002). The substrate 1002 may be provided by a supplier or fabricated. The substrate 1002 may include a stacked ETS constructed in accordance with aspects of the disclosure.

The method couples (at 1110) at least one integrated device (e.g., 1003) to the first surface of the substrate (e.g., 1002). For example, the integrated device 1003 may be coupled to the substrate 1002 through the plurality of pillar interconnects 1032 and the plurality of solder interconnects 1030. The plurality of pillar interconnects 1032 may be optional. The plurality of solder interconnects 1030 are coupled to the plurality of embedded pads 1022. A solder reflow process may be used to couple the integrated device 1003 to the plurality of interconnects through the plurality of solder interconnects 1030.

The method also couples (at 1110) at least one integrated passive device (e.g., 1005) to the first surface of the substrate (e.g., 1002). For example, the integrated passive device 1005 may be coupled to the substrate 1002 through the plurality of pillar interconnects 1052 and the plurality of solder interconnects 1050. The plurality of pillar interconnects 1052 may be optional. The plurality of solder interconnects 1050 are coupled to the plurality of embedded pads 1022. A solder reflow process may be used to couple the integrated passive device 1005 to the plurality of interconnects through the plurality of solder interconnects 1050.

The method couples (at 1115) a plurality of solder interconnects (e.g., 1010) to the second surface of the substrate (e.g., 1002). A solder reflow process may be used to couple the plurality of solder interconnects 1010 to the substrate.

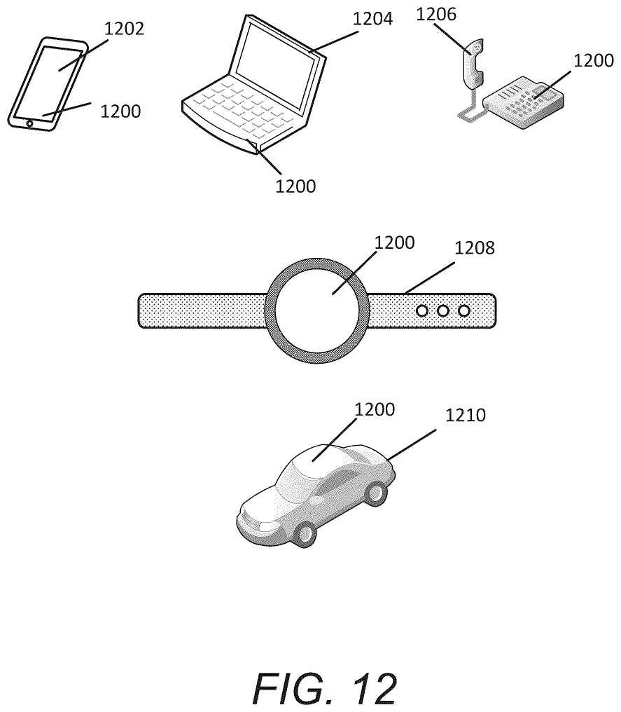

FIG. 12 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 1202, a laptop computer device 1204, a fixed location terminal device 1206, a wearable device 1208, or automotive vehicle 1214 may include a device 1200 as described herein. The device 1200 may be, for example, any of the devices and/or integrated circuit (IC) packages described herein. The devices 1202, 1204, 1206 and 1208 and the vehicle 1210 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:

Aspect 1. An electronic device, comprising: a substrate, the substrate comprising: at least two stacked embedded trace substrates (ETS); a first dielectric layer disposed between an internally facing surface of a first ETS of the at least two stacked ETS with an internally facing surface of a second ETS of the at least two stacked ETS; and a first set of one or more metal connectors that extends through the first dielectric layer and couples a first set of one or more metal structures at the internally facing surface of the first ETS with a second set of one or more metal structures at the internally facing surface of the second ETS.

Aspect 2. The electronic device of aspect 1, wherein: the first set of one or more metal structures at the internally facing surface of the first ETS comprises one or more raised pads; and the second set of one or more metal structures at the internally facing surface of the second ETS comprises one or more embedded pads.

Aspect 3. The electronic device of aspect 2, wherein the first set of one or more metal structures extending through the first dielectric layer comprises: at least one metallized bump disposed between at least one of the one or more embedded pads of the second ETS and at least one of the one or more raised pads of the first ETS.

Aspect 4. The electronic device of aspect 3, wherein: the at least one metallized bump is formed from a metal different than a metal used to form the one or more embedded pads and the one or more raised pads.

Aspect 5. The electronic device of any of aspects 1 to 4, wherein: the first ETS includes a first outer surface including one or more embedded pads disposed in a second dielectric layer.

Aspect 6. The electronic device of aspect 5, further comprising: an integrated circuit (IC) component disposed on the first outer surface of the first ETS and electrically connected to the one or more embedded pads of the first ETS.

Aspect 7. The electronic device of aspect 6, wherein: the IC component is disposed on the first outer surface of the first ETS without a solder mask layer at the first outer surface of the first ETS.

Aspect 8. The electronic device of any of aspects 1 to 7, wherein: the second ETS includes a second outer surface including one or more exposed embedded pads disposed in a third dielectric layer.

Aspect 9. The electronic device of aspect 8, further comprising: one or more solder joints connecting the one or more exposed embedded pads to one or more metal terminals of a printed circuit board.

Aspect 10. The electronic device of aspect 9, wherein: the second outer surface of the second ETS is disposed on the printed circuit board without an intermediate solder mask layer formed on the second outer surface of the second ETS.

Aspect 11. The electronic device of any of aspects 1 to 10, wherein: the first ETS and the second ETS are each multilayer ETS structures.

Aspect 12. The electronic device of aspect 11, wherein: the first ETS is a three-layer ETS structure; the second ETS is a three-layer ETS structure; or a combination thereof.

Aspect 13. The electronic device of any of aspects 1 to 12, wherein the electronic device comprises at least one of: a music player; a video player; an entertainment unit; a navigation device; a communications device; a mobile device; a mobile phone; a smartphone; a personal digital assistant; a fixed location terminal; a tablet computer, a computer; a wearable device; a laptop computer; a server; an internet of things (IoT) device; or a device in an automotive vehicle.

Aspect 14. A substrate comprising: at least two stacked embedded trace substrates (ETS) overlying one another; a first dielectric layer joining an internally facing surface of a first ETS of the at least two stacked ETS with an internally facing surface of a second ETS of the at least two stacked ETS; and a first set of one or more metal structures extending through the first dielectric layer and connecting a first set of one or more metal structures at the internally facing surface of the first ETS with a second set of one or more metal structures at the internally facing surface of the second ETS.

Aspect 15. The substrate of aspect 14, wherein: the first set of one or more metal structures at the internally facing surface of the first ETS comprises one or more raised pads; and the second set of one or more metal structures at the internally facing surface of the second ETS comprises one or more embedded pads.

Aspect 16. The substrate of aspect 15, wherein the first set of one or more metal connectors extending through the first dielectric layer comprises: at least one metallized bump disposed between at least one of the one or more embedded pads of the second ETS and at least one of the one or more raised pads of the first ETS.

Aspect 17. The substrate of aspect 16, wherein: the at least one metallized bump is formed from a metal different than a metal used to form the one or more embedded pads and the one or more raised pads.

Aspect 18. The substrate of any of aspects 14 to 17, wherein: the first ETS includes a first outer surface including one or more embedded pads disposed in a second dielectric layer.

Aspect 19. The substrate of any of aspects 14 to 18, wherein: the second ETS includes a second outer surface including one or more exposed embedded pads disposed in a third dielectric layer.

Aspect 20. The substrate of any of aspects 14 to 19, wherein: the first ETS and the second ETS are each multilayer ETS structures.

Aspect 21. The substrate of aspect 20, wherein: the first ETS is a three-layer ETS structure; the second ETS is a three-layer ETS structure; or a combination thereof.

Aspect 22. A method of fabricating a substrate, comprising: aligning at least two stacked embedded trace substrates (ETS) to overlie one another, wherein the at least two stacked ETS include a first ETS having an internally facing surface having a first set of one or more metal connectors, and a second ETS having an internally facing surface having a first set of one or more metal structures; aligning a first dielectric layer between the internally facing surface of the first ETS and the internally facing surface of the second ETS; and joining the internally facing surface of the first ETS and the internally facing surface of the second ETS with the first dielectric layer, wherein the joining connects at least one metal structure of the first set of one or more metal connectors at the internally facing surface of the first ETS with at least one metal structure of the first set of one or more metal structures at the internally facing surface of the second ETS.

Aspect 23. The method of aspect 22, wherein: the first set of one or more metal connectors at the internally facing surface of the first ETS includes one or more raised pads; and the first set of one or more metal structures at the internally facing surface of the second ETS include one or more embedded pads.

Aspect 24. The method of aspect 23, further comprising: forming at least one metallized bump disposed between at least one embedded pad of the second ETS and at least one raised pad of the first ETS.

Aspect 25. The method of aspect 24, wherein: the at least one metallized bump is formed from a metal different than a metal used to form the at least one embedded pad of the second ETS and the at least one raised pad of the first ETS.

Aspect 26. The method of any of aspects 22 to 25, wherein: the first ETS includes a first outer surface having one or more embedded pads disposed in a second dielectric layer.

Aspect 27. The method of any of aspects 22 to 26, wherein: the second ETS includes a second outer surface having one or more exposed embedded pads disposed in a third dielectric layer.

Aspect 28. The method of any of aspects 22 to 27, wherein: the first ETS and the second ETS are each multilayer ETS structures.

Aspect 29. The method of any of aspects 22 to 28, further comprising: forming the first ETS; and forming the second ETS.

Aspect 30. The method of aspect 29, wherein: the first ETS is formed as a three-layer ETS structure; the second ETS is formed as a three-layer ETS structure; or the first ETS and second ETS are each formed as three-layer structures.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on the bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect (s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An electronic device, comprising:
a substrate, the substrate comprising:
at least two stacked embedded trace substrates (ETS);
a first dielectric layer disposed between an internally facing surface of a first ETS of the at least two stacked ETS with an internally facing surface of a second ETS of the at least two stacked ETS; and
a first set of one or more metal connectors that extends through the first dielectric layer and couples a first set of one or more metal structures at the internally facing surface of the first ETS with a second set of one or more metal structures at the internally facing surface of the second ETS.

2. The electronic device of claim 1, wherein:
the first set of one or more metal structures at the internally facing surface of the first ETS comprises one or more raised pads; and
the second set of one or more metal structures at the internally facing surface of the second ETS comprises one or more embedded pads.

3. The electronic device of claim 2, wherein the first set of one or more metal structures extending through the first dielectric layer comprises:
at least one metallized bump disposed between at least one of the one or more embedded pads of the second ETS and at least one of the one or more raised pads of the first ETS.

4. The electronic device of claim 3, wherein:
the at least one metallized bump is formed from a metal different than a metal used to form the one or more embedded pads and the one or more raised pads.

5. The electronic device of claim 1, wherein:
the first ETS includes a first outer surface including one or more embedded pads disposed in a second dielectric layer.

6. The electronic device of claim 5, further comprising:
an integrated circuit (IC) component disposed on the first outer surface of the first ETS and electrically connected to the one or more embedded pads of the first ETS.

7. The electronic device of claim 6, wherein:
the IC component is disposed on the first outer surface of the first ETS without a solder mask layer at the first outer surface of the first ETS.

8. The electronic device of claim 1, wherein:
the second ETS includes a second outer surface including one or more exposed embedded pads disposed in a third dielectric layer.

9. The electronic device of claim 8, further comprising:
one or more solder joints connecting the one or more exposed embedded pads to one or more metal terminals of a printed circuit board.

10. The electronic device of claim 9, wherein:
the second outer surface of the second ETS is disposed on the printed circuit board without an intermediate solder mask layer formed on the second outer surface of the second ETS.

11. The electronic device of claim 1, wherein:
the first ETS and the second ETS are each multilayer ETS structures.

12. The electronic device of claim 11, wherein:
the first ETS is a three-layer ETS structure;
the second ETS is a three-layer ETS structure; or
a combination thereof.

13. The electronic device of claim 1, wherein the electronic device comprises at least one of:
a music player;
a video player;
an entertainment unit;
a navigation device;
a communications device;
a mobile device;
a mobile phone;
a smartphone;
a personal digital assistant;
a fixed location terminal;
a tablet computer, a computer;
a wearable device;
a laptop computer;
a server;
an internet of things (IoT) device; or
a device in an automotive vehicle.

14. A substrate comprising:
at least two stacked embedded trace substrates (ETS) overlying one another;
a first dielectric layer joining an internally facing surface of a first ETS of the at least two stacked ETS with an internally facing surface of a second ETS of the at least two stacked ETS; and
a first set of one or more metal structures extending through the first dielectric layer and connecting a first set of one or more metal structures at the internally facing surface of the first ETS with a second set of one or more metal structures at the internally facing surface of the second ETS.

15. The substrate of claim 14, wherein:
the first set of one or more metal structures at the internally facing surface of the first ETS comprises one or more raised pads; and
the second set of one or more metal structures at the internally facing surface of the second ETS comprises one or more embedded pads.

16. The substrate of claim 15, wherein the first set of one or more metal structures extending through the first dielectric layer comprises:
at least one metallized bump disposed between at least one of the one or more embedded pads of the second ETS and at least one of the one or more raised pads of the first ETS.

17. The substrate of claim 16, wherein:
the at least one metallized bump is formed from a metal different than a metal used to form the one or more embedded pads and the one or more raised pads.

18. The substrate of claim 14, wherein:
the first ETS includes a first outer surface including one or more embedded pads disposed in a second dielectric layer.

19. The substrate of claim 14, wherein:
the second ETS includes a second outer surface including one or more exposed embedded pads disposed in a third dielectric layer.

20. The substrate of claim 14, wherein:
the first ETS and the second ETS are each multilayer ETS structures.

21. The substrate of claim 20, wherein:
the first ETS is a three-layer ETS structure;
the second ETS is a three-layer ETS structure; or
a combination thereof.

22. A method of fabricating a substrate, comprising:
aligning at least two stacked embedded trace substrates (ETS) to overlie one another, wherein the at least two stacked ETS include a first ETS having an internally facing surface having a first set of one or more metal connectors, and a second ETS having an internally facing surface having a first set of one or more metal structures;
aligning a first dielectric layer between the internally facing surface of the first ETS and the internally facing surface of the second ETS; and
joining the internally facing surface of the first ETS and the internally facing surface of the second ETS with the first dielectric layer, wherein the joining connects at least one metal structure of the first set of one or more metal connectors at the internally facing surface of the first ETS with at least one metal structure of the first set of one or more metal structures at the internally facing surface of the second ETS.

23. The method of claim 22, wherein:
the first set of one or more metal connectors at the internally facing surface of the first ETS includes one or more raised pads; and
the first set of one or more metal structures at the internally facing surface of the second ETS include one or more embedded pads.

24. The method of claim 23, further comprising:
forming at least one metallized bump disposed between at least one embedded pad of the second ETS and at least one raised pad of the first ETS.

25. The method of claim 24, wherein:
the at least one metallized bump is formed from a metal different than a metal used to form the at least one embedded pad of the second ETS and the at least one raised pad of the first ETS.

26. The method of claim 22, wherein:
the first ETS includes a first outer surface having one or more embedded pads disposed in a second dielectric layer.

27. The method of claim 22, wherein:
the second ETS includes a second outer surface having one or more exposed embedded pads disposed in a third dielectric layer.

28. The method of claim 22, wherein:
the first ETS and the second ETS are each multilayer ETS structures.

29. The method of claim 22, further comprising:
forming the first ETS; and
forming the second ETS.

30. The method of claim 29, wherein:
the first ETS is formed as a three-layer ETS structure;
the second ETS is formed as a three-layer ETS structure; or
the first ETS and second ETS are each formed as three-layer structures.
